(19) United States
(12) Patent Application Publication
(10) Pub. No.: US 2010/0244027 A1
(43) Pub. Date: Sep. 30, 2010

(54) Semiconductor device and method of controlling the same

(75) Inventor: Ken Numata, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: ELPIDA MEMORY, INC., Tokyo (JP)

(21) Appl. No.: 12/659,941

(22) Filed: Mar. 25, 2010

(30) Foreign Application Priority Data
Mar. 27, 2009 (JP) P2009-077891

(51) Int. Cl. H01L 29/92; H01L 27/06

(52) U.S. Cl. 257/48; 257/532; 257/E29.343; 257/E27.013

(57) ABSTRACT

A semiconductor device includes a capacitor element that stores charge to perform as a memory that stores information. The capacitor may include, but is not limited to, an insulating layer, a first electrode, and a second electrode. The insulating layer includes metal oxide. The insulating layer has a high dielectric constant. The first electrode contacts with a first surface of the insulating layer. The first electrode is made of a first conductive material including at least one of precious metals and compounds thereof. The second electrode contacts with a second surface of the insulating layer. The second electrode is made of a second conductive material including at least one of metals and compounds thereof. The metals are different from the precious metals. The second conductive material is lower in work function than the first conductive material. The first electrode is lower in potential than the second electrode.

### BACKGROUND OF THE INVENTION

1. Field of the Invention

The present invention relates to a semiconductor device and a method of controlling the semiconductor device. Particularly, the invention relates to a semiconductor device which includes a capacitor capable of storing electric charge, and the semiconductor device capable of storing information specified by electric charge.

Priority is claimed on Japanese Patent Application No. 2009-077891, filed Mar. 27, 2009, the content of which is incorporated herein by reference.

2. Description of the Related Art

DRAMs (Dynamic Random Access Memories) and FRAMs (Ferroelectric Random Access Memories) are known as a semiconductor device including capacitors that each store electric charge representing information.

It is known to a person skilled in the art to which the invention pertains that materials such as SiON may be applied for insulating layers of capacitors, and Si may be applied for a pair of electrodes sandwiching the insulating layer.

A first voltage Vcc, 0V, or Vcc/2 is applied to a first one of paired electrodes and a second voltage Vcc or 0V is applied to a second one of paired electrodes. The second voltage varies depending on electric charges stored in the capacitor. Generally, in such a capacitor included in the semiconductor device, the first voltage is set at a half of the voltage Vcc.

When the first voltage is Vcc/2, a voltage across the insulating layer is controlled to be not higher than Vcc/2, and then a leakage of current through the insulating layer is suppressed independent of the second voltage Vcc or 0V.

Japanese Unexamined Patent Application, First Publications, Nos. 11-168200, 9-191087 and 2003-109952 disclose that recently it has been examined to apply high dielectrics for insulating layers to increase the capacity of capacitor. It has been examined to apply precious metals for paired electrodes of capacitors. For example, Japanese Unexamined Patent Application, First Publication, No. 11-168200 describes that a semiconductor device includes capacitors each having an insulating layer of high dielectric materials such as perovskite oxides and top and bottom electrodes of Pt sandwiching the insulating layer.

### SUMMARY

In one embodiment, a semiconductor device may include, but is not limited to, a capacitor element that stores charge to perform as a memory that stores information. The capacitor may include, but is not limited to, an insulating layer, a first electrode, and a second electrode. The insulating layer includes metal oxide. The insulating layer has a high dielectric constant. The first electrode contacts with a first surface of the insulating layer. The first electrode is made of a first conductive material including at least one of precious metals and compounds thereof. The second electrode contacts with a second surface of the insulating layer. The second electrode is made of a second conductive material including at least one of metals and compounds thereof. The metals are different from the precious metals. The second conductive material is lower in work function than the first conductive material. The first electrode is lower in potential than the second electrode.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a diagram illustrating the movement of electrons between the paired electrodes of a capacitor;

FIG. 1B is a diagram illustrating the movement of electrons between the paired electrodes of a capacitor;

FIG. 2 is a plan view illustrating a semiconductor memory device in accordance with a first embodiment of the present invention;

FIG. 3 is a plan view illustrating the semiconductor memory device, taken along an A-A′ line of FIG. 2;

FIG. 4 is a block diagram illustrating a semiconductor device in accordance with the first embodiment of the present invention;

FIG. 5 is a circuit diagram illustrating a memory cell array and a sense amplifier included in the semiconductor device of FIG. 4;

FIG. 6 is a circuit diagram illustrating a global sense amplifier included in the sense amplifier of FIG. 5;

FIG. 7A is a waveform illustrating read operation of the sense amplifier;

FIG. 7B is a waveform illustrating read operation of the sense amplifier; and

FIG. 8 is a diagram illustrating a leakage of current of a capacitor in examples.

### DETAILED DESCRIPTION OF THE PREFERRED EMBODIMENTS

In one embodiment, a semiconductor device may include, but is not limited to, a capacitor element that stores charge to perform as a memory that stores information. The capacitor may include, but is not limited to, an insulating layer, a first electrode, and a second electrode. The insulating layer includes metal oxide. The insulating layer has a high dielectric constant. The first electrode contacts with a first surface of the insulating layer. The first electrode is made of a first conductive material including at least one of precious metals and compounds thereof. The second electrode contacts with a second surface of the insulating layer. The second electrode is made of a second conductive material including at least one of metals and compounds thereof. The metals are different from the precious metals. The second conductive material is lower in work function than the first conductive material. The first electrode is lower in potential than the second electrode.

The first conductive material may include at least one of Au, Rh, Ru, Pd, Os, Ir, and Pt.

The second conductive material may include at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

The insulating layer may include perovskite oxide.

The insulating layer may include at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)})O₃, PbZrₓTi_{y}Nb_{(1-x-y)}O₃, SrBi₂Ta₂O₉, and CaTiO₃.

The first electrode may be applied with one of a power voltage and a ground voltage, and the second electrode may be applied with one of the power voltage and the ground voltage.

The first electrode may be a plate electrode.

The power voltage may be equal to or lower than 1V.

In another embodiment, a semiconductor device may include, but is not limited to, a capacitor element and a detector. The capacitor element stores charge to perform as a memory that stores information. The capacitor may include, but is not limited to, an insulating layer, a plate electrode, and a storage electrode. The insulating layer includes metal oxide. The insulating layer has a high dielectric constant. The plate electrode contacts with a first surface of the insulating layer. The plate electrode is applied with a ground voltage. The plate electrode may be made of a first conductive material including at least one of precious metals and compounds thereof. A storage electrode contacts with a second surface of the insulating layer. The storage electrode is made of a second conductive material including at least one of metals and compounds thereof. The metals are different from the precious metals. The second conductive material is lower in work function than the first conductive material. The detector detects whether or not memory information is stored in the capacitor based on a potential of the storage electrode.

The first conductive material may include at least one of Au, Rh, Ru, Pd, Os, Ir, and Pt.

The second conductive material may include at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

The insulating layer may include perovskite oxide.

The insulating layer may include at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎Zr_{y}Ti_{(1-y)}O₃, PbZrₓTi_{y}Nb_{(1-x-y)}O₃, SrBi₂Ta₂O₉, and CaTiO₃.

In another embodiment, a semiconductor device may include, but is not limited to, a capacitor element that stores charge to perform as a memory that stores information, and a detector that detects whether or not memory information is stored in the capacitor based on a potential of the storage electrode. The capacitor may include, but is not limited to, an insulating layer including metal oxide, a storage electrode and a plate electrode. The insulating layer has a high dielectric constant. The storage electrode contacts with a first surface of the insulating layer. The storage electrode is made of a first conductive material including at least one of precious metals and compounds thereof. The plate electrode contacts with a second surface of the insulating layer. The plate electrode is applied with a power voltage. The plate electrode is made of a second conductive material including at least one of metals and compounds thereof. The metals are different from the precious metals. The second conductive material is lower in work function than the first conductive material.

The first conductive material may include at least one of Au, Rh, Ru, Pd, Os, Ir, and Pt.

The second conductive material may include at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Th, Np, Pu, Tm, Er, Ho, Y, Ay, Gd, Sm, Nd, Pr, Ce, La, Ac, Ca, Lu, Li, Sr, Na, Ra, Ba, K, Rb, Cs, and Fr.

The insulating layer may include perovskite oxide.

The insulating layer may include at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

In an additional embodiment, a method of controlling a semiconductor device may be provided. The semiconductor device may include, but is not limited to, a capacitor element that stores charge to perform as a memory that stores information. The capacitor may include, but is not limited to, an insulating layer including metal oxide. The insulating layer has a high dielectric constant. A first electrode contacts with a first surface of the insulating layer. The first electrode is made of a first conductive material including at least one of precious metals and compounds thereof. A second electrode contacts with a second surface of the insulating layer. The second electrode is made of a second conductive material including at least one of metals and compounds thereof. The metals are different from the precious metals. The second conductive material is lower in work function than the first conductive material. The method may include, but is not limited to, applying a ground voltage to the first electrode; applying a power voltage or a ground voltage to the second electrode, thereby writing or reading a memory information into or from the capacitor.

The first conductive material may include at least one of Au, Rh, Ru, Pd, Os, Ir, and Pt.

The second conductive material may include at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

The insulating layer may include perovskite oxide.

The insulating layer may include at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

In a further additional embodiment, a method of controlling a semiconductor device is provided. The semiconductor device may include, but is not limited to, a capacitor element that stores charge to perform as a memory that stores information. The capacitor may include, but is not limited to, an insulating layer including metal oxide, a first electrode, and a second electrode. The insulating layer has a high dielectric constant. The first electrode contacts with a first surface of the insulating layer. The first electrode is made of a first conductive material inclwiing at least one of precious metals and compounds thereof. The second electrode contacts with a second surface of the insulating layer. The second electrode is made of a second conductive material including at least one of metals and compounds thereof. The metals are different from the precious metals. The second conductive material is lower in work function than the first conductive material. The method may include, but is not limited to, applying a power voltage or a ground voltage to the first electrode; and applying the power voltage to the second electrode, thereby writing or reading a memory information into or from the capacitor.

The first conductive material may include at least one of Au, Rh, Ru, Pd, Os, Ir, and Pt.

The second conductive material may include at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

The insulating layer may include perovskite oxide.

The insulating layer may include at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

The invention will be now described herein with reference to illustrative embodiments. Those skilled in the art will recognize that many alternative embodiments can be accomplished using the teaching of the present invention and that the invention is not limited to the embodiments illustrated for explanatory purpose.

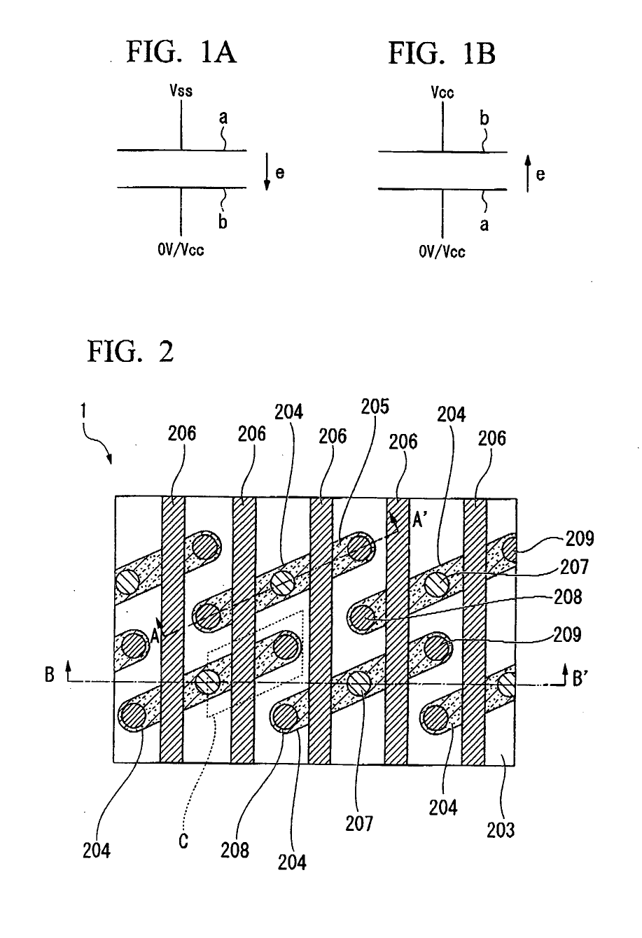

High dielectric metal oxides are applied for insulating layers of capacitors. The insulating layer is sandwiched between paired electrodes (first and second electrodes). The paired electrodes are different in material from each other. The first electrode has a first work function. The second electrode has a second work function. The first work function is greater than the second work function. In some cases, the first voltage may be equal to the second voltage. In other cases, the first voltage may be smaller than the second voltage. When the first voltage is set to be smaller than the second voltage, a potential difference is caused between the paired electrodes. The potential difference causes electrons to move in the capacitors from the first electrode to the second electrode. FIGS. 1A and 1B illustrate the movement of electrons between the paired electrodes of the capacitor. In FIGS. 1A and 1B, signs “a” and “b” refer the first and second electrodes, respectively.

FIG. 1A shows that a ground voltage Vss(=0) is applied to the first electrode “a” and a voltage 0[V] or Vcc(>0) is applied to the second electrode “b”, wherein the voltage 0[V] or Vcc(>0) corresponds to the stored information 0 or 1 in the capacitor. In any cases, the voltage applied to the first electrode “a” is equal to or smaller than that to the second electrode “b”. Electrons move from the first electrode “a” to the second electrode “b” only if the voltage Vcc(>0) is applied to the second electrode “b”. No potential difference is caused between the first electrode “a” and the second electrode “b” if the voltage Vcc(>0) is not applied to the second electrode “b”.

FIG. 1B shows that a voltage 0[V] or Vcc(>0) is applied to the first electrode “a”, wherein the voltage 0[V] or Vcc(>0) corresponds to the stored information 0 or 1 in the capacitor, and that a voltage Vcc(>0)[V] is applied to the second electrode “b”. The potential of the first electrode “a” is always equal to or smaller than that of the second electrode “b”. Electrons move from the first electrode “a” to the second electrode “b” only if the voltage 0[V] is applied to the first electrode “a”. No potential difference is caused between the first electrode “a” and the second electrode “b” if the voltage Vcc(>0) is applied to the first electrode “a”.

In FIGS. 1A and 1B, if the potential difference is caused between the two electrodes, then electrons move only from the first electrode “a” to the second electrode “b”, wherein the first electrode “a” has the first work function larger than the second work function of the second electrode “b”. It should be noted that no electrons move from the second electrode “b” to the first electrode “a”. Although FIGS. 1A and 1B show that another leakage of current may be caused by the material of the second electrode “b”, the other leakage of current is ignorable and controllable efficiently.

### First Embodiment

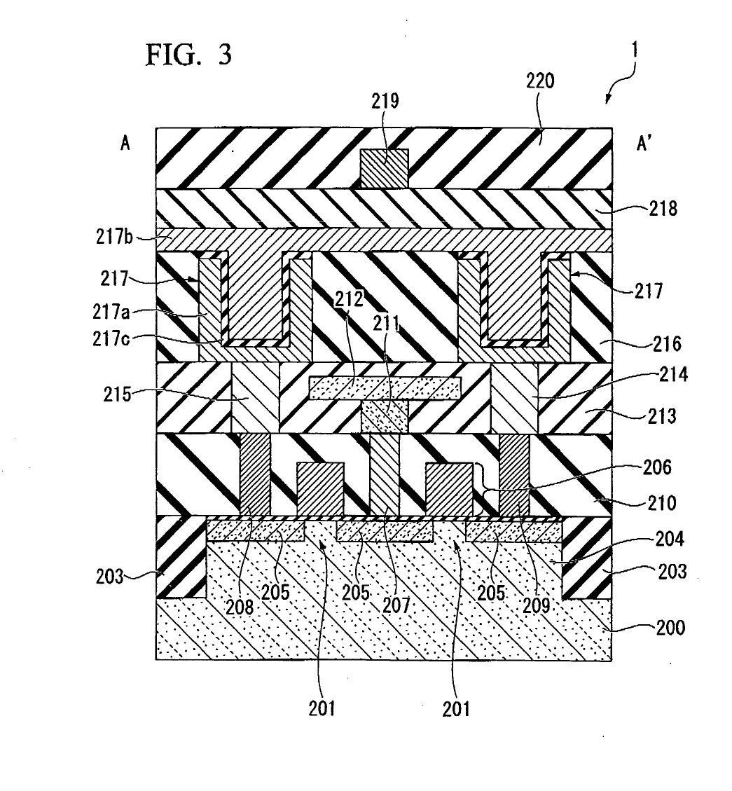

As an example of a semiconductor device and a method of forming the same, a DRAM is illustrated, which stores the information specified by electric charge storing on a capacitor. FIG. 2 is a fragmentary plan view illustrating a cell array area of the DRAM in accordance with the first embodiment of the present invention. FIG. 3 is a fragmentary cross sectional elevation view of the cell array area, taken along an A-A′ line of FIG. 2. In this embodiment, active regions or diffusion layer regions are formed on a P-type silicon substrate 200. Active regions 204 are each isolated by an isolation region 203. The device isolation region 203 is made of an insulator such as silicon oxide. In general, the device isolation region 203 can be a field oxide film in the P-type silicon substrate 200.

Gate electrodes 206 are disposed over the P-type silicon substrate 200. The gate electrodes 206 cross over the active regions 204. The gate electrodes 206 perform as not only control electrodes but also word lines of the DRAM. Each active region 204 has a first region which is not covered by the gate electrodes 206. The first region is ion-implanted with impurities such as phosphorus ions. The first region forms an N-type diffusion layer region 205. The N-type diffusion layer regions 205 perform as source and drain regions of a field effect transistor 201 illustrated in FIGS. 2 and 3. In FIG. 2, the field effect transistor 201 is encompassed by dashed line C.

FIGS. 2 and 3 illustrate that a contact plug 207 is disposed in the center portion of the active region 204, and that contact plugs 208 and 209 are disposed in the opposite end portions of the active region 204. The contact plugs 207, 208, and 209 contact with the N-type diffusion layer region 205. The N-type diffusion layer region 205 is disposed on the upper surface of the active region 204. In this embodiment, the active region 204 has a pair of transistors which is adjacent. The paired transistors share the contact plug 207 to form a pair of memory cells at high density. Wiring layers 212 illustrated in FIG. 3 contact with the contact plugs 207. Each wiring layer 212 extends in a direction perpendicular to the direction along which the gate electrode 206 extends. Each wiring layer 212 extends in parallel to a B-B′ line of FIG. 2. The wiring layers 212 perform as bit lines of the DRAM. The paired contact plugs 208 and 209 are eclectically connected to a capacitor 217 illustrated in FIG. 3.

FIG. 3 illustrates that the N-type diffusion layer region 205 is connected to the contact plugs 207, 208, and 209. In this embodiment, the contact plugs 207, 208, and 209 may be made of polysilicon with phosphorus. FIG. 3 illustrates an interlayer dielectric film 210 over the field effect transistor 201. The contact plug 207 is connected to the wiring layer 212 through a contact plug 211. The wiring layer 212 is made of tungsten. The contact plugs 208 and 209 are connected to the capacitor 217 through contact plugs 215 and 214, respectively. FIG. 3 illustrates interlayer dielectric films 213, 216, and 218. FIG. 3 also illustrates that a wiring layer 219 made of aluminum is disposed over the interlayer dielectric film 218. FIG. 3 also illustrates a surface protection film 220.

The DRAM 10 includes the capacitors 217. Each capacitor 217 has a storage electrode 217a, a plate electrode 217b, and an insulating layer 217c. The plate electrode 217b is provided to contact with a first surface of the insulating layer 217c. The storage electrode 217a is provided to contact with a second surface of the insulating layer 217c.

The three-dimensional structure of the capacitor 217 will hereinafter be described with reference to FIG. 3. The storage electrode 217a forms a hollow cylinder with a closed bottom. The insulating layer 217c covers the inside wall and the upper surface of the storage electrode 217a. The plate electrode 217b covers the inside wall and the upper surface of the insulating layer 217c. As illustrated in FIG. 3, the plate electrode 217b covers the insulating layers 217c of the capacitors 217. The plate electrode 217b performs as a common top electrode for the capacitors 217.

The capacitors in this embodiment may form any shapes. The shapes are not limited to the three-dimensional structures as above mentioned. The capacitor may include paired plane electrodes and an insulating layer. The capacitor may include first and second electrodes and an insulating layer. The first electrode is farther from the substrate than the second electrode. The second electrode may be cylindrically shaped. The insulating layer covers the side and top surfaces of the second electrode. The first electrode may be disposed on the insulating layer. The first electrode covers the outside and top surfaces of the insulating layer. The second electrode and the insulating layer are enclosed by the first electrode. The bottoms of the second electrode and the insulating layer are not covered by the first electrode. The bottom of the second electrode is not covered by the insulating layer. The first and second electrodes are electrically separated from each other by the insulating layer. In cases that strictly limited area is available for the capacitor, the three-dimensional structures will generally be more suitable than the two-dimensional structures to ensure high capacitance of the memory cell capacitor.

In this embodiment, the ground voltage is applied to the plate electrode 217b. The power voltage Vcc or 0V is selectively applied to the storage electrode 217a through the field effect transistor 201. The power voltage Vcc or 0V corresponds to the stored information 1 or 0 in the capacitor. The potential of the plate electrode 217b is less than that of the storage electrode 217a when the power voltage Vcc is applied to the storage electrode 217a. In this embodiment, the stored information in the capacitor 217 can be detected by detecting the potential of the storage electrode 217a. Namely, charge stored in the capacitor 217 can be detected by detecting the potential of the storage electrode 217a.

In this embodiment, the insulating layer 217c of the capacitor 217 may be made of the high dielectric metal oxides. The plate electrode 217b may be made of precious metals. The storage electrode 217a may be made of metallic materials except for the precious metals above mentioned. The storage electrode 217a has a work function which is smaller than that of the plate electrode 217b.

Insulating materials such perovskite oxides may be applied for the insulating layer 217c. In some cases, the insulating layer 217c may be made of one or more the perovskite oxides. The insulating layer 217c may include, but is not limited to, at least one of perovskite oxides selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, CaTiO₃. The insulating layer 217c may include, but is not limited to, at least one of perovskite oxides such as Bi₄Ti₃O₁₂, La₂Ti₂O₇, and (Zr,Sn)TiO₄. The insulating layers 217c may also include, but is not limited to, ZrO₂, Al₂O₃, and TiO₂ which dielectric constant are not as high as those of perovskite oxides.

In this embodiment, the dielectric constant of the insulating layer 217c may be made of metal oxides with dielectric constants which are lower than those of perovskite oxides. In some cases, a preferable range of the dielectric constant of the insulating layer 217c is from 8 to 300. The plate electrode 217b may be made of precious metals or compounds thereof which are in general large in work function. Electrons are unlikely to transport from the plate electrode 217b to the insulating layer 217c even though the dielectric constant of the insulating layer 217c is in the above range.

Among the materials for the insulating layer 217c, SrTiO₃ is preferable because it is a ternary compound which is simple, even binary compounds such as Al₂O₃, TiO₂, and ZrO₂ are simpler. The dielectric constant of SrTiO₃ is relatively high, for example, 300. The dielectric constant of SrTiO₃ has no ferroelectric phase, even the ferroelectric phase disturbs the control.

The plate electrode 217b may include, but is not limited to, at least one of precious metals or compounds thereof which are selected from Au, Rh, Ru, Pd, Os, Ir, and Pt. These precious metals are larger in work function and hard to be oxidized even when the precious metals contact with the first surface of the insulating layer 217c. In this embodiment, the work function φ [eV] of each material is calculated as follows:

φ=2.27x+0.34.

here x means Pauling electronegativity.

Precious metal elements, which are known to a person skilled in the art, are listed in the order of the magnitude of work function as follows:

Au(5.788 eV), Rh(5.5156 eV), Ru(5.334 eV), Pd(5.334 eV), Os(5.334 eV), Ir(5.334 eV), Pt(5.334 eV), Mo(5.2432 eV), Tc(5.107 eV), Sb(4.9935 eV), Ge(4.9027 eV), Po(4.88 eV), Sn(4.7892 eV), and Ag(4.7211 eV).

The work function of each precious metal element is mentioned. The precious metal elements can be applied for the plate electrode 217b. The material having a larger work function is more preferable for the electrode.

The plate electrode 217b contacts with the high dielectric metal oxide. It is preferred that the plate electrode 217b is hard to be oxidized. Au, Rh, Ru, Pd, Os, Ir, Pt, and Tc are hard to be oxidized. Since Tc is not present in nature, it is not practical to use Tc for the plate electrodes 217b.

The precious metal compounds used for the plate electrode 217b may be, but are not limited to, RuO₂ and IrOₓ. It is preferred that the plate electrode 217b includes at least one of precious metal compounds selected from Au, Rh, Ru, Pd, Os, Ir, and Pt, for example, PtₓIr(1−x) and PtₓRu(1−x).

Pt is preferable for the plate electrode 217b because Pt has been used as an industrial material. The production and distribution of Pt has been established. Further, Pt has widely been studied as an electrode for high dielectric material.

The storage electrode 217a may preferably include at least one of below-listed metals, except for precious metals, and compounds thereof which are smaller in work function than the plate electrode 217b:

Ni(4.6757 eV), Si(4.653 eV), Cu(4.653 eV), Re(4.653 eV), Hg(4.653 eV), Bi(4.653 eV), Co(4.6076 eV), Fe(4.4941 eV), Ga(4.4487 eV), Tl(4.426 eV), Pb(4.426 eV), In(4.3806 eV), W(4.199 eV), U(4.199 eV), Cd(4.1763 eV), Cr(4.1082 eV), Zn(4.0855 eV), V(4.0401 eV), Al(3.9947 eV), Nb(3.972 eV), Be(3.9039 eV), Mn(3.8585 eV), Ti(3.8358 eV), Ta(3.745 eV), Pa(3.745 eV), Sc(3.4272 eV), Zr(3.3591 eV), Mg(3.3137 eV), Hf(3.291 eV), Th(3.291 eV), Np(3.291 eV), Pu(3.291 eV), Tm(3.1775 eV), Er(3.1548 eV), Ho(3.1321 eV), Y(3.1094 eV), Dy(3.1094e′V), Gd(3.064 eV), Sm(2.9959 eV), Nd(2.9278 eV), Pr(2.9051 eV), Ce(2.8824 eV), La(2.837 eV), Ac(2.837 eV), Ca(2.61 eV), Lu(2.61 eV), Li(2.5646 eV), Sr(2.4965 eV), Na(2.4511 eV), Ra(2.383 eV), Ba(2.3603 eV), K(2.2014 eV), Rb(2.2014 eV), Cs(2.1333 eV), and Fr(1.929 eV).

The above-described elements are listed in the order of the magnitude of work function. Si is not metal but usable for the storage electrode 217a.

Titanium nitride (TiN), tungsten nitride (WN), and tantalum nitride (TaN) can also be used for the storage electrode 217a. TiN is more preferable because TiN is commonly used in semiconductor manufacturing, TiN has oxidation resistance, and TiN is not excessively oxidized when a perovskite oxide film is formed in an oxygen atmosphere.

One of preferable structures of the capacitor 217 in this embodiment is illustrated as follows. The plate electrode 217b may preferably be made of a precious metal with a large work function such as Pt, Ru, or Ir. The insulating layer 217c may preferably be made of a high dielectric material such as SrTiO₃. The storage electrodes 217a may preferably be made of titanium nitride, tungsten nitride, or tantalum nitride. The plate electrode 217b may preferably be made of the precious metal having large work function. The insulating layer 217c may preferably be made of the high dielectric material. The storage electrodes 217a may preferably be made of the oxidation resistance.

The capacitor of the DRAM 10 in this embodiment can be formed as follows. The storage electrode 217a can be formed by a chemical vapor deposition CVD or a physical vapor deposition PVD method. The insulating layer can be formed by the CVD, the PVD, or an atomic layer deposition ALD method. The plate electrode 217b is formed by the CVD or the PVD method.

### Method of Controlling the Semiconductor Device:

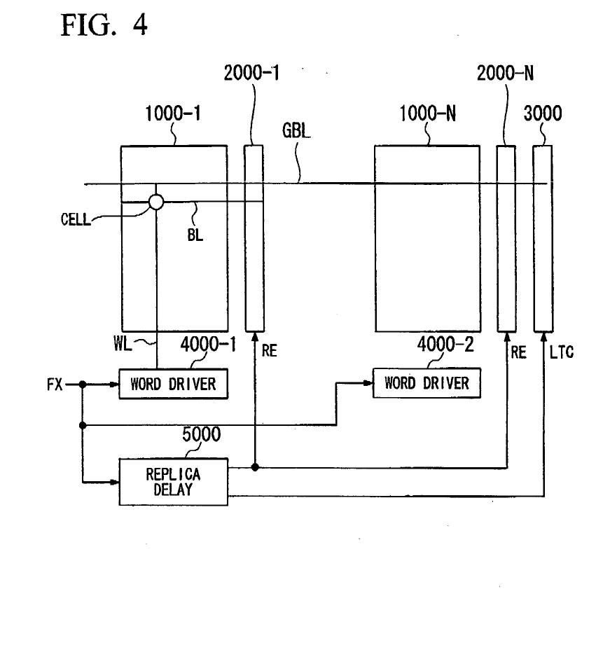

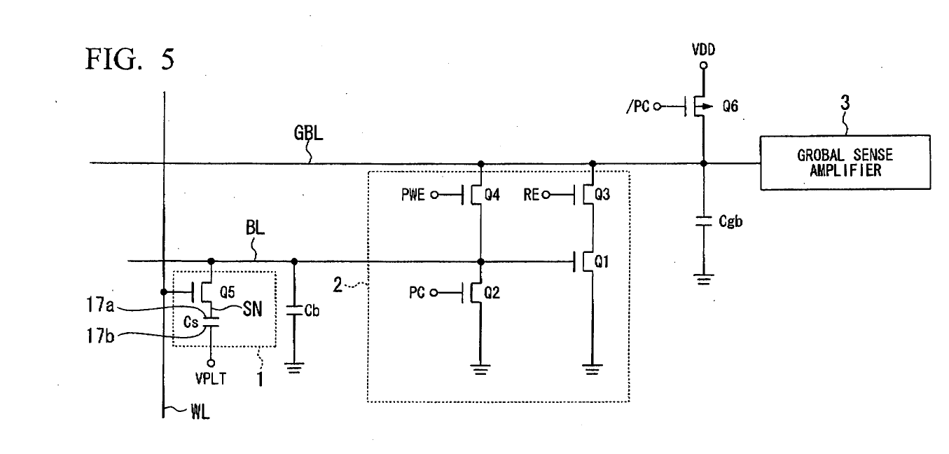

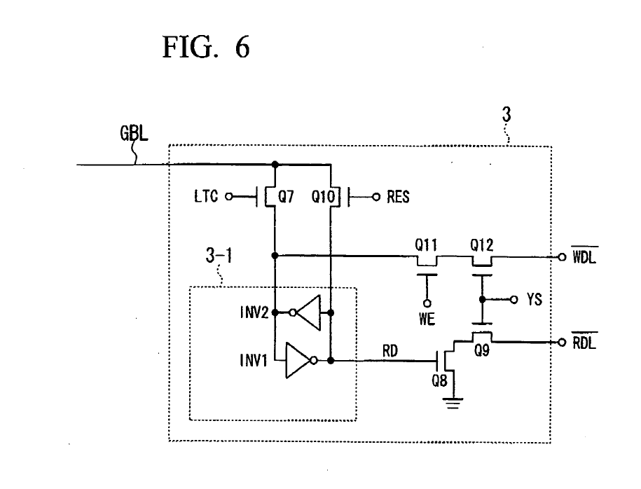

A method of controlling the DRAM including the capacitors 217 will be described below. The power voltage VDD or the ground voltage is applied to the storage electrode 217a. Ground voltage is applied to the plate electrode 217b. As illustrated in FIGS. 4, 5, and 6, it is possible to read or write the storing information from or to the capacitor 217. FIG. 4 is a circuit diagram illustrating a memory sensing system of the DRAM of this embodiment. FIG. 5 is a circuit diagram illustrating a memory cell array and a sense amplifier shown in FIG. 4. FIG. 6 is a circuit diagram illustrating a global sense amplifier shown in FIG. 5.

### Overall Configuration:

In FIG. 4, plural pairs of a memory cell array 1000 and a sense amplifier 2000 are aligned in the direction parallel to the extension direction of bit lines BL. Each memory cell array has word lines WL, bit lines BL, and memory cells CELL. The bit line BL corresponds to the wiring layer 212 in FIG. 3. The word line WL corresponds to the gate electrode 206 in FIGS. 2 and 3. The bit line BL is connected to a corresponding sense amplifier 2000. Each memory cell CELL is disposed at a crossing point of the word line WL and the bit line BL. When the word line WL selects one memory cell CELL, the stored signal is read out of the memory cell CELL to the bit line BL. The sense amplifier 2000 amplifies the signal on the bit line BL and supplies the amplified signal to the global bit line GBL.

FIG. 4 illustrates a circuit diagram illustrating the DRAM with a memory sensing system in accordance with this embodiment. The DRAM includes plural pares of memory cell arrays 1000-1, . . . 1000-N and sense amplifier columns 2000-1, . . . 2000-N. The plural pares of the memory cell arrays 1000-1 to 1000-N and the sense amplifier columns 2000-1 to 2000-N are aligned in the direction parallel to the extension direction of bit lines BL. A global sense amplifier column 3000 is provided for the alignment of the plural pares of the memory cell arrays 1000-1 to 1000-N and the sense amplifier columns 2000-1 to 2000-N. Each global bit line GBL extends over the aligned plural pares of the memory cell arrays 1000-1 to 1000-N and the sense amplifier columns 2000-1 to 2000-N. The global sense amplifier column 3000 is connected through the global bit lines GBL to the sense amplifier columns 2000-1 to 2000-N. The sense amplifier columns 2000-1 to 2000-N are connected through bit lines BL to the memory cell arrays 1000-1 to 1000-N, respectively. Word drivers 4000-1 to 4000-N are provided for the memory cell arrays 1000-1 to 1000-N, respectively. The word drivers 4000-1 to 4000-N are connected through word lines WL to the memory cell arrays 1000-1 to 1000-N, respectively. A replica delay circuit 5000 is provided for the sense amplifier columns 2000-1 to 2000-N and the global sense amplifier column 3000. The replica delay circuit 5000 is connected to each of the sense amplifier columns 2000-1 to 2000-N and the global sense amplifier column 3000. Each memory cell array 1000-1, . . . 1000-N has word lines WL, bit lines BL, and memory cells CELL.

Each of the bit lines BL can be short by forming pairs of the memory cell arrays 1000-1 to 1000-N and the sense amplifier columns 2000-1 to 2000-N, respectively. Area of the circuit diagram can be small by disposing the global bit lines GBL which runs over the pares of the memory cell arrays 1000-1 to 1000-N and the sense amplifier columns 2000-1 to 2000-N. The replica delay circuit 5000 supplies selecting signals RE to each of the sense amplifier columns 2000-1 to 2000-N. The replica delay circuit 5000 supplies a selecting signal LTC to the global sense amplifier column 3000. Upon receipt of an FX signal, each of the word drivers 4000-1 to 4000-N drives word lines WL of a corresponding one of the memory cell arrays 1000-1 to 1000-N which are paired with the word drivers 4000-1 to 4000-N, respectively. Upon receipt of the FX signal, the replica delay circuit 5000 generates selecting signals RE and LTC. Upon receipt of the selecting signal RE, each of the sense amplifier columns 2000-1 to 2000-N performs sensing of bit lines BL of a corresponding one of the memory cell arrays 1000-1 to 1000-N which are paired with the sense amplifier columns 2000-1 to 2000-N, respectively. Upon receipt of the selecting signal LTC, the global sense amplifier column 3000 performs sensing of the global bit lines GBL which run over the aligned plural pares of the memory cell arrays 1000-1 to 1000-N and the sense amplifier columns 2000-1 to 2000-N.

The FX signal is supplied to each of the replica delay circuit 5000 and the word drivers 4000-1 to 4000-N. In response to the FX signal, the selecting signal RE is supplied from the replica delay circuit 5000 to each of the sense amplifier columns 2000-1 to 2000-N. In response to the FX signal, the selecting signal LTC is supplied from the replica delay circuit 5000 to the global sense amplifier column 3000.

### Configuration of the Memory Cell and the Sense Amplifier:

FIG. 5 illustrates the word line WL, the bit line BL, the memory cell 1, the sense amplifier 2, the global bit line GBL, and the global sense amplifier 3. The word line WL corresponds to the gate electrode 206 in FIGS. 2 and 3. The bit line BL corresponds to the wiring layer 212 in FIG. 3. The memory cell 1 is formed at intersection of the word line WL and the bit line BL.

The sense amplifier 2 includes an NMOS transistor Q1, Q2, Q3, and Q4. A gate electrode of the NMOS transistor Q1 is connected to the bit line BL. The NMOS transistor Q1 senses a signal read from the bit line BL. The NMOS transistor Q1 amplifies the signal read from the bit line BL and converts it into a drain current. When a high logic state pre-charged signal PC is input to a gate electrode of the NMOS transistor Q2, the bit line BL is pre-charged in the ground voltage Vss.

The NMOS transistor Q3 operates as a read select transistor of the sense amplifier 2. When a gate electrode of the NMOS transistor Q3 receives a signal RE, the NMOS transistor Q3 connects a drain electrode of the NMOS transistor Q1 with the global bit line GBL. The NMOS transistor Q4 operates as a write select transistor of the sense amplifier 2. When a gate electrode of the NMOS transistor Q4 receives a signal RWE, the NMOS transistor Q4 connects the bit line BL with the global bit line GBL.

The bit lines BL and the memory cell 1 are connected to the global bit line GBL through other sense amplifiers. In the read operation, the NMOS transistor Q3 connects only the sense amplifier 2, which a selected memory cell 1 belongs to, with the global bit line GBL. When the NMOS transistor Q1 drives the global bit line GBL in accordance with the signal read from the bit line BL, the global sense amplifier 3 latches a signal transferred to the global bit line GBL, and the global sense amplifier 3 outputs to external circuits.

In write operation, the NMOS transistor Q4 connects only the sense amplifier 2, which a selected memory cell 1 belongs to, with the global bit line GBL. When the global sense amplifier 3 receives writing data from external circuits and drives the global bit line GBL, the bit line BL is driven through the NMOS transistor Q4. As a result, some data are written to the memory cell 1.

The memory cell 1 includes an NMOS transistor Q5 and a capacitor Cs that stores electric charges representing information. The NMOS transistor Q5 corresponds to the MOS transistor 201 in FIGS. 2 and 3. The capacitor Cs corresponds to the capacitor 217 in FIG. 3. The NMOS transistor Q5 includes a gate electrode 17e, a drain electrode 17c, and a source electrode 17d. The capacitor Cs includes paired electrodes 17a and 17b. The gate electrode 17e is connected to the word line WL, which corresponds to the gate electrode 206 in FIGS. 2 and 3. The drain electrode 17c, which corresponds to the N-type diffusion layer region 205 in FIG. 3, is connected to the bit line BL, which corresponds to the wiring layer 212 in FIG. 3. The source electrode 17d, which corresponds to the N-type diffusion layer region 205, is connected to one electrode 17a of the paired electrodes, which corresponds to the storage electrode 217a in FIG. 3. The NMOS transistor Q5 connects the bit line BL with the electrode 17a. Therefore the NMOS transistor Q5 and the bit line BL can control electric charges stored in the capacitor Cs. The electric charges represent information. The memory cell 1 is operated to memorize the information.

The power voltage VDD, Vcc or 0V corresponding to stored information is applied to the electrode 17a of the capacitor Cs in FIG. 5, through the NMOS transistor Q5. The other electrode 17b of the capacitor Cs is connected to the cell plate potential VPLT. The electrode 17b corresponds to the plate electrode 217b in FIG. 3. The cell plate potential VPLT is set at the ground voltage Vss. In any case, the potential of the electrode 17b is equal to or smaller than that of the electrode 17a. Only if the power voltage VDD is applied to the electrode 17a, the charges are stored in the capacitor Cs.

The bit line BL is connected to memory cells not illustrated in FIG. 5. In this embodiment, a capacitance of the capacitor Cs is set at 20fF, and a parasitic capacitance Cb of the bit line BL is set at 10fF. The bit line BL reads a signal by sharing charges with the capacitor Cs. In the read operation, after driving the NMOS transistor Q5 and sharing charges, the bit line BL obtains enough potential caused by stored electrons in a few nano seconds. If sensing time is set at a few nano seconds, then the NMOS transistor Q5 of the sense amplifier 2 can sense and amplify signals with accuracy. According to the above mentioned principle, a number of the memory cells connected to the bit line BL is set that a required signal of charge sharing is obtained.

A PMOS transistor Q6 is connected to the global bit line GBL. The gate electrode of the PMOS transistor Q6 receives a signal /PC. The signal /PC is an inverted signal of a pre-charged signal PC. When the signal /PC is in low logic state, the PMOS transistor Q6 pre-charges the global bit line GBL to the power voltage VDD. The global bit line GBL has a parasitic capacitance Cgb.

### Configuration of the Global Sense Amplifier:

In FIG. 6, the global sense amplifier includes NMOS transistors Q7, Q8, Q9, Q10, Q11, and Q12 and a latch circuit. The latch circuit includes an inverter 1 and a inverter 2. In the read operation, a gate electrode LTC of the NMOS transistor Q7 is in high logic state and the NMOS transistor Q7 is driven. The latch circuit judges the logic state of a readout signal on the global bit line GBL. A voltage for inverted logic state of the global bit line GBL is obtained as an output RD of the latch circuit. A signal YS is obtained at the gate electrode of the NMOS transistors Q9 and Q12. When the signal YS is in high logic state, a voltage for the signal is output to a read signal line RDL through a series circuit of the NMOS transistors Q8 and Q9.

After a voltage for output RD of the latch circuit is determined, rewrite operation is triggered. When the gate electrode LTC is in low logic state and a gate electrode RES of the NMOS transistor Q10 is in high logic state, a power of the NMOS transistor Q7 is off and a power of the NMOS transistor Q10 is on. The inverter 1 drives the global bit line GBL with data of the output RD. By driving the global bit line GBL, rewriting data drives the bit line BL through the NMOS transistor Q4. Electron in the memory cell 1 is restored.

In write operation, the gate electrode LTC in FIGS. 4 and 6 is in low logic state, and the gate electrode RES in FIG. 6 is in high logic state. The power of the NMOS transistor Q7 is off. The power of NMOS transistor Q10 is on. The power of the NMOS transistor Q11 is on. When the signal YS of the global sense amplifier 3 is in high logic state, the power of the NMOS transistor Q12 is on. A voltage of a write signal line WDL drives the global bit line GBL through the NMOS transistor Q12, Q11, Q10, and the inverter 1. A voltage of the global bit line GBL drives the bit line BL through the NMOS transistor Q4. Information of stored electrons is written to the memory cell 11.

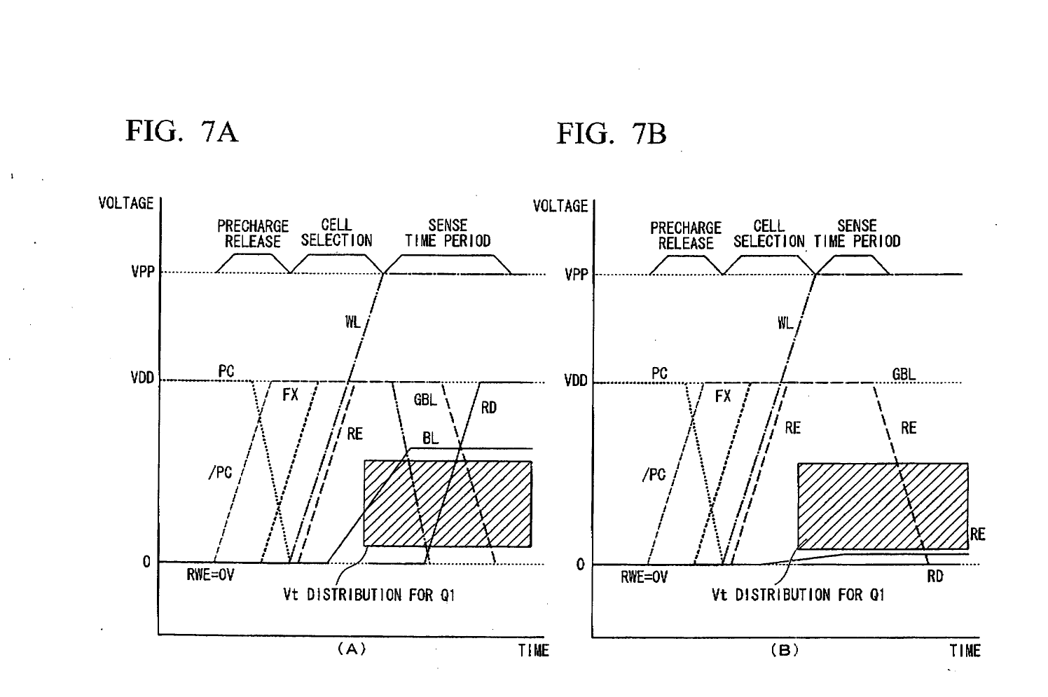

Read operating waveforms of the sense amplifier 2 are illustrated below. Such as read operating waveforms of a PVT variation compensation sense amplifier are illustrated in FIG. 7. The PVT variation compensation sense amplifier equips a replica delay circuit of the RE signal without variations of manufacturing process, power voltage, and junction temperature. In the FIG. 7, a horizontal axis indicates time, and a vertical axis indicates voltage. FIG. 7A shows that high “H”-data is read from the memory cell. FIG. 7B shows that low “L”-data is read from the memory cell.

FIG. 7A illustrates to read high logic state data from the memory cell 1. The read operation of the sense amplifier 2 includes non-pre-charged period, cell selection period, and sense period. In the non-pre-charged period, the signal PC changes to low logic state, and the signal/PC changes to high logic state. The power of the NMOS transistor Q2 and the PMOS transistor Q6 are off. The voltage of the bit line BL is floated and held at 0V. The voltage of the global bit line GBL is pre-charged and held at VDD.

When the cell selection period starts, the signal FX changes to high logic state. When the word line WL and the gate electrode RE change to high logic state, a signal for the high logic state is read from the memory cell 1 to the bit line BL, then the sense period starts. In sense period, since the voltage of the bit line BL is larger than upper limit threshold voltage Vt of the NMOS transistor Q1, a drain current of the NMOS transistor Q1 increases. Electrons are discharged fast from a parasitic capacitance Cgb of the global bit line GBL. The voltage of the global bit line GBL varies from the power voltage VDD to the ground voltage Vcc.

The voltage of the global bit line GBL is judged low logic state by the latched circuit. Then the output RD of the latch circuit is inverted and in high logic state. When the gate electrode RE of the NMOS transistor Q3 is in low logic state, the bit line BL and the global bit line GBL are separated, then the sense period finishes. The threshold voltage Vt distribution of the NMOS transistor Q1 is due to manufacturing variation such as gate oxide thickness variation and channel impurity distribution.

FIG. 7B illustrates to read high low logic state data from the memory cell 1. The read operation of the sense amplifier 2 includes non-pre-charged period, cell selection period, and sense period. In the non-pre-charged period, the signal PC changes to low logic state, and the signal /PC changes to high logic state. The power of the NMOS transistor Q2 and the PMOS transistor Q6 are off. The voltage of the bit line BL is floated and held at 0V. The voltage of the global bit line GBL is pre-charged and held at the power voltage VDD.

When the cell selection period starts, the signal FX is transitioned to high logic state. When the word line WL and the gate electrode RE change to high logic state, a signal for the low logic state is read from the memory cell 1 to the bit line BL, then the sense period starts. In sense period, since the voltage of the bit line BL is smaller than lower limit threshold voltage Vt of the NMOS transistor Q1, a drain current of the NMOS transistor Q1 is not driven. Electrons are not discharged from a parasitic capacitance Cgb of the global bit line GBL. The voltage of the global bit line GBL is held at the power voltage VDD. The voltage of the global bit line GBL is judged high logic state by the latched circuit. Then the output RD of the latch circuit maintains low logic state. When the gate electrode RE of the NMOS transistor Q3 is in low logic state, the bit line BL and the global bit line GBL are separated, then the sense period finishes.

When the cell selection period starts, the signal FX is transitioned to high logic state. When the word line WL and the gate electrode RE change to high logic state, a signal for the low logic state is read from the memory cell 1 to the bit line BL, then the sense period starts. In sense period, since the voltage of the bit line BL is smaller than lower limit threshold voltage Vt of the NMOS transistor Q1, a drain current of the NMOS transistor Q1 is not driven. Electrons are not discharged from a parasitic capacitance Cgb of the global bit line GBL. The voltage of the global bit line GBL is held at the power voltage VDD. The voltage of the global bit line GBL is judged high logic state by the latched circuit. Then the output RD of the latch circuit maintains low logic state. When the gate electrode RE of the NMOS transistor Q3 is in low logic state, the bit line BL and the global bit line GBL are separated, then the sense period finishes.

In this embodiment, the capacitor 217 is provided with the storage electrode 217a, the plate electrode 217b, and the insulating layer 217c. The insulating layer 217c is made of high dielectric metal oxide. The plate electrode 217b is made of precious metals. The plate electrode 217b contacts with the insulating layer 217c at the first surface thereof. The storage electrode 217a is made of metallic materials except for the precious metals mentioned above. The storage electrode 217a is formed to contact with the insulating layer 217c at the second surface thereof. The work function of the storage electrode 217a is smaller than that of the plate electrode 217b. When the potential of the plate electrode 217b is set to be less than the potential of the storage electrode 217a, electrons can move only from the plate electrode 217b to the storage electrode 217a.

Accordingly, the leakage of current depending on metallic materials of the storage electrode 217a is ignorable and controllable efficiently. The flexibility to select the metallic materials becomes high. The storage electrode 217a can be made of the metallic materials that are easy for micro-fabrication. The capacitor 217 can be micro-fabricated. The plate electrode 217b is made of the precious metals with the large work functions. The leakage of current between the plate electrode 217b and the insulating layer 217c is suppressed, and thin insulating layers may be applied. Capacities of capacitors per unit area can be increased. The capacitor 217 can be micro-fabricated.

In this embodiment, one block of the plate electrode 217b is formed to cover the insulating layers 217c. Area of the plate electrode 217b may be larger than that of the storage electrodes 217a. If a precious metal to make the plate electrodes 217b is difficult to be micro-fabricated, the precious metal can be applied to make the capacitor 217 micro-fabricated.

In this embodiment, the ground voltage is applied to the plate electrode 217b, and the power voltage VDD or the ground voltage is applied to the storage electrode 217a. The read operation, which means reading information from the capacitor 217, and write operation, which means writing information to the capacitor 217, can be performed under conditions mentioned above. In the read or write operation, as the power voltage VDD decreases, the leakage of current on the capacitor 217 decreaes.

If the power voltage VDD applied to the storage electrode 217a is set at 1V or less, the leakage of current on the capacitor 217 is suppressed more effectively.

The DRAM in this embodiment equips the capacitor 217 with a high dielectric insulating layer 217c, and a leakage of current on each capacitor 217 can be suppressed. Thus the DRAM in this embodiment is great in refreshing character of charges on each capacitor 217.

### Second Embodiment

The semiconductor device and the method of controlling the semiconductor device can be applied to other embodiments except for the first embodiment. In the first embodiment, the plate electrode 217b is made of the precious metals, and the storage electrode 217a is made of some metals except for the precious metals. In a second embodiment, materials to form the plate electrode 217b and the storage electrode 217a may be exchanged each other. In such a case, the potential of the storage electrode 217a must be less than that of the plate electrode 217b.

The ground voltage 0V and the power voltage VDD correspond to the stored information 0 and 1 respectively in the capacitor 217. A condition for applied voltages in the second embodiment is illustrated as follows. The ground voltage 0V or the power voltage VDD is applied to the storage electrode 217a. The power voltage VDD is applied to the plate electrode 217b. In any case, the potential of the storage electrode 217a is set to be less than that of the plate electrode 217b. Only if the ground voltage 0V is applied to the storage electrode 217a, the electrons can move from the storage electrode 217a to the plate electrode 217b.

The materials to form the plate electrode 217b and the storage electrode 217a are exchanged between the first embodiment and this embodiment. The electrons move from one electrode with larger work function to the other electrode with smaller work function.

The DRAM in this embodiment is controlled by the condition for the applied voltages above mentioned. The DRAM in this embodiment operates to read and write the stored information for the capacitor 217.

In this embodiment, the potential of the storage electrode 217a is set to be less than the potential of the plate electrode 217b. The potential difference causes between the storage electrode 217a and the plate electrode 217b. The elections move from the storage electrode 217a to the plate electrode 217b. A leakage of current, which is caused by electrons moving from the electrode 217b to the electrode 217a and depends on the material of the plate electrode 217b, is ignorable and controllable efficiently. The flexibility to select the materials of the plate electrode 217b is extended. The plate electrode 217b can be made of a material easy to microfabricate. The capacitor 217 can be microfabricated. The storage electrode 217a is made of the precious metals with the large work functions. A leakage of current between the storage electrode 217a and the insulating layer 217c is suppressed. Thin insulating layers may be applied. Capacities of capacitors per unit area can be increased. The capacitor 217 can be micro-fabricated.

The DRAM in this embodiment is controlled by the condition for the applied voltages above mentioned. As the power voltage VDD decreases, the leakage of current descreases.

Embodiments of the semiconductor device and the method of controlling the semiconductor device in this embodiments are not restricted to the first and the second embodiments. According to all disclosures and technical ideas, this invention includes any variation and correction that a person skilled in the art can perform. The DRAM is illustrated as an example of the semiconductor device. The technical ideas in this invention can be applied to not only the DRAM but all semiconductor devices. The semiconductor devices operate to store electric charges representing information in the capacitors.

The above-described embodiments can generally be applicable to any semiconductor devices including memory cells, such as CPU (Central Processing Unit), MCU (Micro Control Unit), DSP (Digital Signal Processor), ASIC (Application Specific Integrated Circuit), and ASSP (Application Specific Standard Circuit). Examples of the products including the semiconductor devices, to which the above-described embodiments can generally be applicable, may be, but are not limited to, SOC (System-On-Chip), MCP (Multi-Chip-Package), and POP (Package-On-Package). The configuration of the voltage differential amplifier circuit is not limited. The transistor used for the memory cell may be, but is not limited to, any available field effect transistors such as metal oxide semiconductor field effect transistors, and metal-insulator semiconductor field effect transistors. nMOS transistors (n-channel MOS transistors) and pMOS transistors (p-channel MOS transistors) are typical examples of the first conductivity type and second conductivity type transistors, respectively. The above embodiments can also be applicable to any types of semiconductor devices in which memory cells and logic devices or MCUs are combined. Namely, the above embodiments can also be applicable to not only any types of memory systems but also other semiconductor systems.

### EXAMPLES

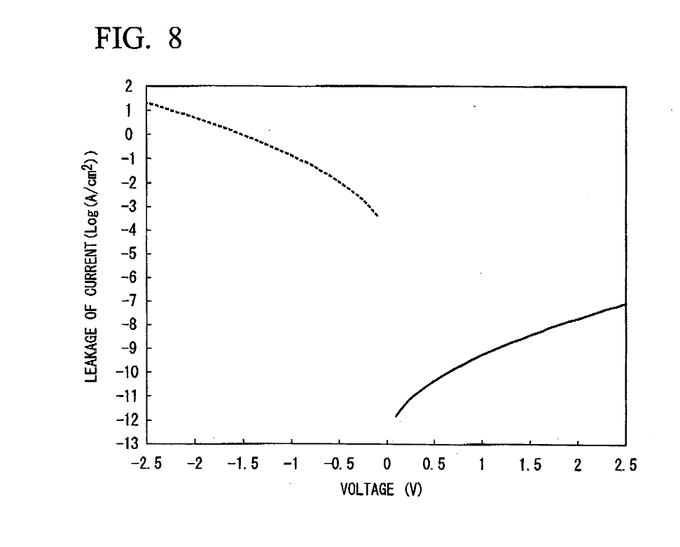

A theoretical value of a leakage of current of a capacitor was calculated in accordance with Equation (3) of Ken Numata, Thin Solid Films 515 (2006) p. 2635. The capacitor has first and second electrodes and an insulating layer. A precious metal or a compound of precious metals was used for the first electrode. A metal except for precious metals or a compound of those metals for precious metals was used for the second electrode. The material for the second electrode is smaller in work function than the material for the first electrode. An insulating material containing metal oxide and having a high dielectric constant is used for the insulating layer. The result of the calculation of the theoretical value of a leakage of current of the capacitor is shown in FIG. 8.

The results shown in FIG. 8 were obtained assuming that the first electrode is made of Pt, the insulating film 13 is made of SrTiO₃ having a thickness of 5 nm, and the second electrode is made of a metal which is lower in work function by 0.5 eV than N.

The leakage of current was calculated in a case where the first electrode has 0V and the second electrode has 0V or 1V. The leakage of current was calculated in another case where the first electrode has 0V or 1V and the second electrode has 0V.

FIG. 8 shows the leakage of current of the capacitor of the embodiment. The real line represents the leakage of current in the first case where the first electrode has 0V and the second electrode has 0V or 1V. The dotted line represents the leakage of current in the second case where the first electrode has 0V or 1V and the second electrode has 0V.

The leakage of current in the first case where the first electrode has 0V and the second electrode has 0V or 1V is smaller than the leakage of current in the second case where the first electrode has 0V or 1V and the second electrode has 0V. This demonstrates that the leakage of current is sufficiently suppressed when the first electrode has 0V and the second electrode has 0V or 1V and the first electrode is lower in potential than the second electrode.

As shown in FIG. 8, the leakage of current is not suppressed in the second case where the first electrode has 0V or 1V and the second electrode has 0V. In accordance with the embodiments of the invention, the potential of the first electrode does not exceed the potential of the second electrode. Thus, the embodiments of the invention do not take the second case where the first electrode has 0V or 1V and the second electrode has 0V.

The terms of degree such as “substantially,” “about,” and “approximately” as used herein mean a reasonable amount of deviation of the modified term such that the end result is not significantly changed. For example, these terms can be construed as including a deviation of at least ±5 percents of the modified term if this deviation would not negate the meaning of the word it modifies.

It is apparent that the present invention is not limited to the above embodiments, but may be modified and changed without departing from the scope and spirit of the invention.

What is claimed is:

1. A semiconductor device comprising:
a capacitor element that stores charge to perform as a memory that stores information, the capacitor comprising:
an insulating layer including metal oxide, the insulating layer having a high dielectric constant;
a first electrode contacting with a first surface of the insulating layer, the first electrode being made of a first conductive material including at least one of precious metals and compounds thereof; and
a second electrode contacting with a second surface of the insulating layer, the second electrode being made of a second conductive material including at least one of metals and compounds thereof, the metals being different from the precious metals, the second conductive material being lower in work function than the first conductive material,
the first electrode being lower in potential than the second electrode.

2. The semiconductor device according to claim 1, wherein the first conductive material includes at least one of Au, Rh, Ru, Pd, Os, Ir, and Pt.

3. The semiconductor device according to claim 1, wherein the second conductive material includes at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

4. The semiconductor device according to claim 2, wherein the second conductive material includes at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

5. The semiconductor device according to claim 1, wherein the insulating layer includes perovskite oxide.

6. The semiconductor device according to claim 2, wherein the insulating layer includes perovskite oxide.

7. The semiconductor device according to claim 3, wherein the insulating layer includes perovskite oxide.

8. The semiconductor device according to claim 4, wherein the insulating layer includes perovskite oxide.

9. The semiconductor device according to claim 1, wherein the insulating layer includes at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

10. The semiconductor device according to claim 2, wherein the insulating layer includes at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

11. The semiconductor device according to claim 3, wherein the insulating layer includes at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTio₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

12. The semiconductor device according to claim 4, wherein the insulating layer includes at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

13. The semiconductor device according to claim 1, wherein the first electrode is applied with one of a power voltage and a ground voltage, and the second electrode is applied with one of the power voltage and the ground voltage.

14. The semiconductor device according to claim 1, wherein the first electrode is a plate electrode.

15. The semiconductor device according to claim 1, wherein the power voltage is equal to or lower than 1V.

16. A semiconductor device comprising:
a capacitor element that stores charge to perform as a memory that stores information, the capacitor comprising:
an insulating layer including metal oxide, the insulating layer having a high dielectric constant;
a plate electrode contacting with a first surface of the insulating layer, the plate electrode being applied with a ground voltage, the plate electrode being made of a first conductive material including at least one of precious metals and compounds thereof;
a storage electrode contacting with a second surface of the insulating layer, the storage electrode being made of a second conductive material including at least one of metals and compounds thereof, the metals being different from the precious metals, the second conductive material being lower in work function than the first conductive material; and
a detector that detects whether or not memory information is stored in the capacitor based on a potential of the storage electrode.

17. The semiconductor device according to claim 16, wherein the first conductive material includes at least one of Au, Rh, Ru, Pd, Os, Ir, and Pt.

18. The semiconductor device according to claim 16, wherein the second conductive material includes at least one of Ni, Si, Cu, Re, Hg, Bi, Co, Fe, Ga, Tl, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

19. The semiconductor device according to claim 16, wherein the insulating layer includes perovskite oxide.

20. The semiconductor device according to claim 16, wherein the insulating layer includes at least one perovskite oxide selected from selected from SrTiO₃, BaTiO₃, BaₓSr₍₁₋ₓ₎TiO₃, BaₓSr₍₁₋ₓ₎Ti_{y}Zr₍₁₋ₓ₎O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.

21. A semiconductor device comprising:
a capacitor element that stores charge to perform as a memory that stores information, the capacitor comprising:
an insulating layer including metal oxide, the insulating layer having a high dielectric constant;
a storage electrode contacting with a first surface of the insulating layer, the storage electrode being made of a first conductive material including at least one of precious metals and compounds thereof;
a plate electrode contacting with a second surface of the insulating layer, the plate electrode being applied with a power voltage, the plate electrode being made of a second conductive material including at least one of metals and compounds thereof, the metals being different from the precious metals, the second conductive material being lower in work function than the first conductive material; and
a detector that detects whether or not memory information is stored in the capacitor based on a potential of the storage electrode.

22. The semiconductor device according to claim 21, wherein the first conductive material includes at least one of Au, Rh, Ru, Pd, Os, Ir, and Pt.

23. The semiconductor device according to claim 21, wherein the second conductive material includes at least one of Ni, Si, Cu, Re, Hg, Bi, Co, Fe, Ga, TI, Pb, In, W, U, Cd, Cr, Zn, V, Al, Nb, Be, Mn, Ti, Ta, Pa, Sc, Zr, Mg, Hf, Th, Np, Pu, Tm, Er, Ho, Y, Dy, Gd, Sm, Nd, Pr, Ce, La, Ac, Ca, Lu, Li, Sr, Na, Ra, Ba, K, Rb, Cs, and Fr.

24. The semiconductor device according to claim 21, wherein the insulating layer includes perovskite oxide.

25. The semiconductor device according to claim 21, wherein the insulating layer includes at least one perovskite oxide selected from selected from SrTiO₃, BaTiO₃, BaₓSr₍₁₋ₓ₎TiO₃, BaₓSr₍₁₋ₓ₎Ti_{y}Zr_{(1-y)}O₃, BaTi₍₁₋ₓ₎SnₓO₃, PbTiO₃, PbZrO₃, PbZrₓTi₍₁₋ₓ₎O₃, (PbₓLa₍₁₋ₓ₎)Zr_{y}Ti_{(1-y)}O₃, PbZrₓTi_{y}Nb_{(1-x-y)}O₃, SrBi₂Ta₂O₉, and CaTiO₃.
